(19) United States
(12) Patent Application Publication
(10) Pub. No.: US 2014/0098976 A1
(43) Pub. Date: Apr. 10, 2014

(54) SPEAKER SYSTEM AND METHOD FOR ADJUSTING POWER OF SPEAKER

(71) Applicant: Chiun Mai Communication Systems, Inc., New Taipei (TW)

(72) Inventor: CHENG-PING LIU, New Taipei (TW)

(73) Assignee: Chiun Mai Communication Systems, Inc., New Taipei (TW)

(21) Appl. No.: 14/014,299

(22) Filed: Aug. 29, 2013

(30) Foreign Application Priority Data
Oct. 8, 2012 (TW) 101137175

(51) Int. Cl. H03G 3/00

(52) U.S. Cl. CPC H03G 3/004
USPC 381/120

(57) ABSTRACT

An exemplary speaker system includes a speaker, an audio amplifier, a detecting resistor, and a control unit. The audio amplifier is connected to the speaker and outputs a working voltage to the speaker. The detecting resistor is electronically connected between the speaker and the audio amplifier. The control unit is connected between the detecting resistor and the audio amplifier. The control unit detects a voltage of the detecting resistor, calculates a real-time power of the speaker, and compares the real-time power with a rated power of the speaker. When the real-time power equals to or exceeds the rated power, the control unit adjusts the working voltage until the real-time power is below the rated power.

### BACKGROUND

1. Technical Field

The disclosure generally relates to a speaker system and a method for adjusting a speaker power.

2. Description of the Related Art

When a speaker of an electronic device, such as a mobile phone, or a personal digital assistant, plays audio files, the speaker will be over-loaded due to large audio files or other parameters and may be damaged. A typical method for preventing the speaker from damage is to control power of the speaker by restricting an output power of an audio amplifier provided to the speaker. However, there is a difference among a resistance of the audio amplifier, a resistance of an audio encoder/decoder module, and a resistance of the speaker, thus it is hard to control the power of the speaker accurately.

Therefore, there is room for improvement within the art.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views. Wherever possible, the same reference numbers are used throughout the drawings to refer to the same or like elements of an embodiment.

FIG. 1 is a block diagram of a speaker system, according to an exemplary embodiment.

FIG. 2 is a flowchart of an embodiment of a method for adjusting a power of a speaker.

### DETAILED DESCRIPTION

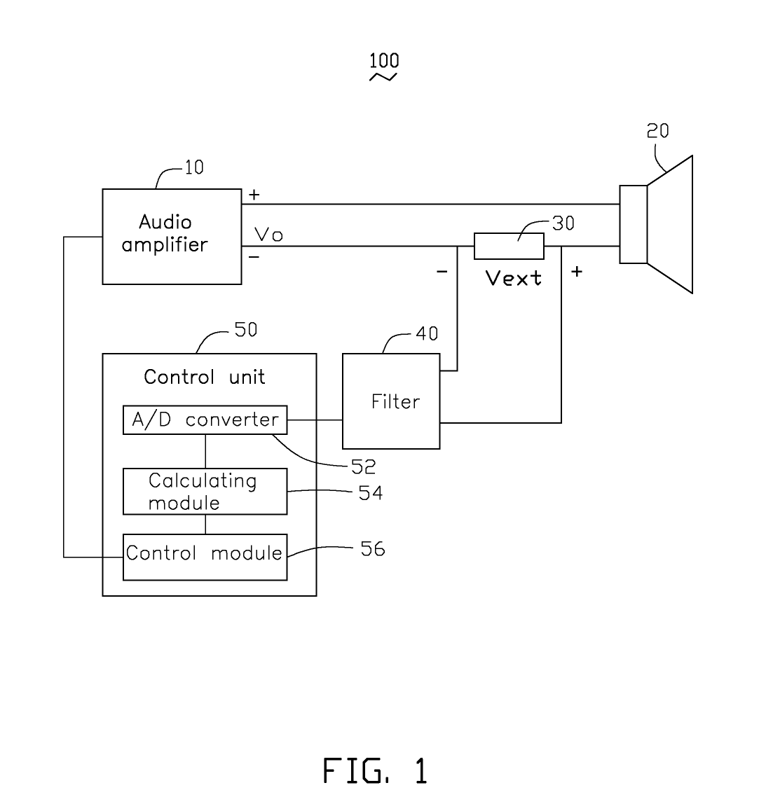

FIG. 1 is a block diagram of a speaker system 100, according to an exemplary embodiment. The speaker system 100 can be used with or in an electronic device (not shown) assembled with a speaker. The electronic device may be a mobile phone or a personal digital assistant, for example.

The speaker system 100 includes an audio amplifier 10, a speaker 20, a detecting resistor 30, a filter 40, and a control unit 50. The audio amplifier 10 is electronically connected to the speaker 20 and outputs a working voltage to the speaker 20. In this embodiment, the voltage value provided by the audio amplifier 20 is Vo.

The speaker 20 is used to play audio files. The speaker 20 has a rated power and a working power corresponding to the working voltage provided by the audio amplifier 10. Generally, when the working power of the speaker 20 is less than the rated power, the speaker 20 works normally. Once the working power equals to or is out of the rated power, the speaker 20 works abnormally and may be damaged.

One end of the detecting resistor 30 is electronically connected to the audio amplifier 10. Another end of the detecting resistor 30 is electronically connected to the speaker 20. In this way, the audio amplifier 10, the speaker 20, and the detecting resistor 30 form a current loop, and current flowing through the speaker 20 equals to current flowing through the detecting resistor 30. Thus, current flowing through the speaker 20 can be detected by the detecting resistor 30. A resistance of the detecting resistor 30 is Rext. In this embodiment, the resistance Rext is less than 1 ohm.

The filter 40 is electronically connected to the detecting resistor 30 in parallel. In this embodiment, the filter 40 is a low-pass filter. The filter 40 filters a high-frequency signal of the speaker system 100, such as a D-type high-frequency signal, thereby obtaining a pure detecting voltage of the detecting resistor 30.

The control unit 50 is electronically connected between the filter 40 and the audio amplifier 10. The control unit 50 may be a central processing unit and includes an analog/digital (A/D) converter 52, a calculating module 54, and a control module 56. The A/D converter 52 is electronically connected to the filter 40. The A/D converter 52 receives a real-time detecting voltage Vext of the detecting resistor 30, converts the detected voltage into a digital signal, and transmits the digital signal to the calculating module 54. According to the detected voltage and the resistance of the detecting resistor 30, the calculating module 54 calculates and obtains a real-time current Iext flowing through the detecting resistor 30 according to a following formula (1):

$$Iext = \frac{Vext}{Rext} \qquad ( 1 )$$

Due to the current flowing through the speaker 20 equaling to the current Iext flowing through the detecting resistor 30, the calculating module 54 further calculates and obtains a real-time working power of the speaker 20 according to a following formula (2):

$$Pext = Vo * \frac{Vext}{Rext} \qquad ( 2 )$$

The control module 56 is capable of comparing the real-time working power of the speaker 20 with the rated power and adjusting the output voltage of the audio amplifier 10 according to the compared result. In detail, the control unit 56 receives the real-time working power of the speaker 20 from the calculating module 54 and compares the real-time working power with the rated power. When the real-time working power is less than the rated power, the control module 56 controls the audio amplifier 10 remaining output voltage value Vo. When the real-time working power equals to or exceeds the rated power, which indicates that the speaker 20 works abnormally and may be damaged. In this way, the control module 56 adjusts the output voltage of the audio amplifier 10 until the real-time working power of the speaker 20 is less than the rated power.

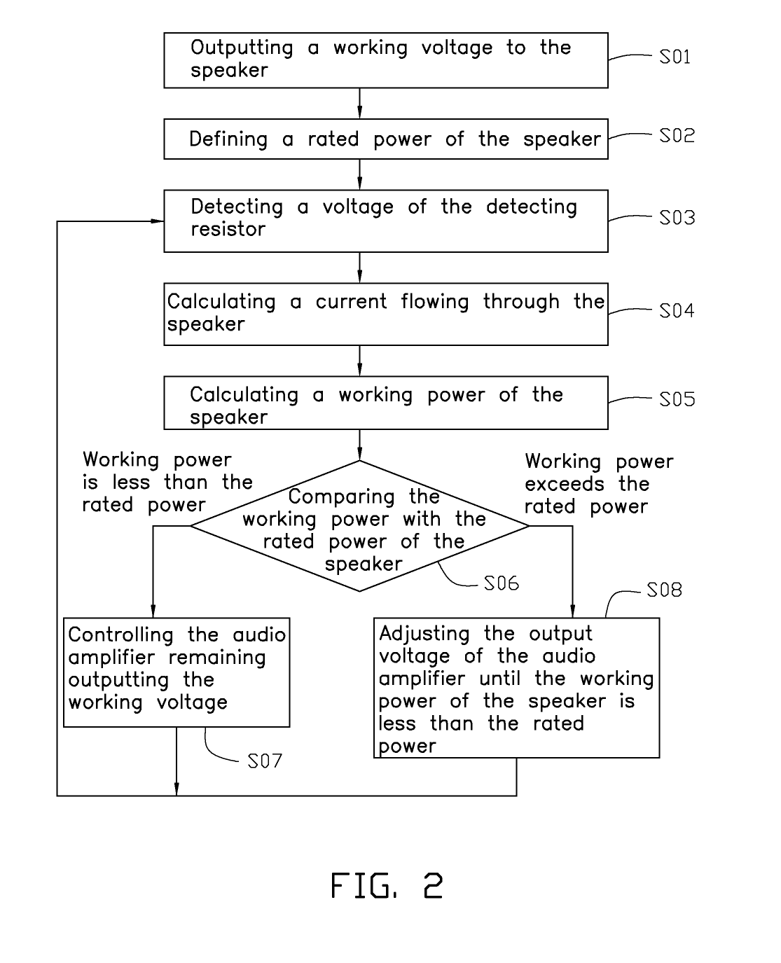

FIG. 2 shows an embodiment of a method for adjusting a power of the speaker 20 includes the following steps.

In step 1, the audio amplifier 10 provides a working voltage to the speaker 20. The working voltage value provided by the audio amplifier 10 is Vo. The audio amplifier 10, the speaker 20, and the detecting resistor 30 form a current loop.

In step 2, the control unit 50 defines a rated power of the speaker 10. When a working power of the speaker 20 is less than the rated power, the speaker 20 works normally. When the working power equals to or is out of the rated power, the speaker 20 works abnormally and may be damaged.

In step 3, the A/D convertor 52 detects a real-time voltage Vext of the detecting resistor 30, converts the detected voltage to a digital signal, and transmits the digital signal to the calculating module 54.

In step 4, the calculating module 54 calculates and obtains a real-time current flowing through the speaker 20 according to the detected voltage and a resistance of the detecting resistor 30.

In step 5, the calculating module 54 further calculates and obtains a real-time working power of the speaker 20 according to the real-time current flowing through the speaker 20 and the working voltage provided by the audio amplifier 10.

In step 6, the control module 56 compares the real-time working power with the rated power of the speaker 20 and adjusts the output voltage of the audio amplifier 10 according to the compared result. In detail, when the real-time working power is less than the rated power, step 7 is implemented. When the real-time working power equals to or is out of the rated power, step 8 is implemented.

In step 7, the control module 56 controls the audio amplifier 10 remaining outputting the working voltage value Vo.

In step 8, the control module 56 adjusts the output voltage of the audio amplifier 10 until the real-time working power of the speaker 20 is less than the rated power.

In summary, the speaker system of this embodiment of the disclosure can detect a working power of the speaker 20 in real-time by detecting a voltage of the detecting resistor 30, and determines whether the working power equals to or exceeds a rated power of the speaker 20, thereby effectively and accurately adjusting the working power of the speaker 20 to prevent the speaker 10 from damage.

In the present specification and claims, the word “a” or “an” preceding an element does not exclude the presence of a plurality of such elements. Further, the word “comprising” does not exclude the presence of elements or steps other than those listed.

It is to be also understood that even though numerous characteristics and advantages of exemplary embodiments have been set forth in the foregoing description, together with details of the structures and functions of the embodiments, the disclosure is illustrative only, and changes may be made in detail, especially in matters of arrangement of parts within the principles of this disclosure to the full extent indicated by the broad general meaning of the terms in which the appended claims are expressed.

What is claimed is:

1. A speaker system, comprising:
a speaker having a rated power;
an audio amplifier electronically connected to the speaker and outputting a working voltage to the speaker;
a detecting resistor, wherein one end of the detecting resistor is electronically connected to the speaker and another end of the detecting resistor is electronically connected to the audio amplifier; and
a control unit electronically connected between the detecting resistor and the audio amplifier, wherein the control unit detects a real-time voltage of the detecting resistor, calculates a real-time power of the speaker, and compares the real-time power with the rated power; when the real-time power equals to or exceeds the rated power, the control unit adjusts the working voltage until the real-time power is below the rated power.

2. The speaker system of claim 1, wherein the real-time power of the speaker is calculated according to the detected voltage, a resistance of the detecting resistor, and the working voltage.

3. The speaker system of claim 1, wherein when the real-time power is less than the rated power, the control unit controls the audio amplifier to retain the working voltage.

4. The speaker system of claim 1, further comprising a filter, wherein the filter is connected between the detecting resistor and the control unit for filtering a high-frequency signal.

5. The speaker system of claim 4, wherein the filter is a low-pass filter.

6. The speaker system of claim 1, wherein the resistance of the detecting resistor is less than 1 ohm.

7. The speaker system of claim 4, wherein the control unit comprises an analog/digital (A/D) converter connected to the filter, the A/D converter receives the detected voltage of the detecting resistor and converts the detected voltage into a digital signal.

8. The speaker system of claim 7, wherein the control unit further comprises a calculating module connected to the A/D converter, the calculating module receives the detected voltage of the detecting resistor and calculates the real-time power according to the detected voltage, the resistance of the detecting resistor, and the working voltage.

9. The power adjustment device of claim 8, wherein the control unit further comprises a control module connected between the calculating module and the audio amplifier, the control module compares the real-time power with the rated power and adjusts the output voltage of the audio amplifier according to the compared result.

10. A method for adjusting a power of a speaker, the method comprising:
providing an audio amplifier and a detecting resistor, the amplifier connected to the speaker and outputting a working voltage to the speaker, the detecting resistor connected between the audio amplifier and the speaker and forming a current loop with the audio amplifier and the speaker;
defining a rated power of the speaker;
detecting a voltage of the detecting resistor;
calculating a real-time current flowing through the speaker and a real-time power of the speaker;
comparing the real-time power with the rated power, and
adjusting the working voltage according to the comparison.

11. The method of claim 10, wherein when the real-time power is less than the rated power, controlling the audio amplifier remaining output the working voltage.

12. The method of claim 10, wherein when the real-time power equals to or exceeds the rated power, adjusting the working voltage until the real-time power is less than the rated power.

13. The method of claim 10, wherein the resistance of the detecting resistor is less than 1 ohm.

14. The method of claim 10, wherein the real-time current of the speaker is obtained by the detected voltage and a resistance of the detecting resistor.

15. The method of claim 14, wherein the real-time power is obtained by the real-time current and the working voltage.
